(19) United States
(12) Patent Application Publication
(10) Pub. No.: US 2006/0127576 A1
(43) Pub. Date: Jun. 15, 2006

(54) Method and process reactor for sequential gas phase deposition by means of a process and an auxiliatry chamber

(76) Inventors: Thomas Hecht, Dresden (DE); Jorn Lutzen, Dresden (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/529,412

(22) PCT Filed: Sep. 24, 2003
(86) PCT No.: PCT/DE03/03188

§ 371 Date: Dec. 21, 2005

(30) Foreign Application Priority Data
Sep. 30, 2002 (DE) 102 45 537.6

(51) Int. Cl. C23C 16/00

(52) U.S. Cl. 427/248.1; 118/715

(57) ABSTRACT

In a process chamber of a process reactor, a sequential gas phase deposition (ALD, atomic layer deposition) of two or more precursors fed in by means of process gases is controlled. The process chamber is connected to an auxiliary chamber for a change of precursor and so the precursor to be removed is rarefied in the process chamber, so that a process duration of the sequential gas phase deposition that is determined by a change of precursor is reduced.

### BACKGROUND

One embodiment of the invention relates to a method for depositing a layer on a substrate arranged in a process chamber of a process reactor by means of a sequential gas phase deposition. In one such process, at least one first process gas and one second process gas are respectively introduced into the process chamber and removed from the process chamber alternately one after the other.

In semiconductor process technology, the depositing of layers for which a high degree of conformity and great homogeneity are required is increasingly being performed by means of sequential gas phase deposition (ALD, atomic layer deposition).

In a first phase of an ALD process, a first precursor material (precursor) is fed in a gaseous phase to a process chamber in which a substrate is located. By a process referred to as chemisorption, the precursor is deposited in activated portions of a substrate surface of the substrate. The first precursor is generally chemically modified thereby. Once all the activated portions of the substrate surface are covered with the modified precursor material, the first process phase of the deposition is complete and a monomolecular partial monolayer comprising a modified first precursor has been deposited on the substrate surface. Then, fractions of the first precursor that have not been deposited are removed from the process chamber by purging with an inert purging gas and/or by being pumped out. In a second phase, a second precursor is introduced into the process chamber and is deposited almost exclusively on the partial monolayer. The precursors are thereby transformed into the layer material. This leads to the formation of a monolayer of the layer which is to be produced. After removal of undeposited fractions of the second precursor from the process chamber, a single process cycle of the ALD process is complete. The method steps of the process cycle are repeated until a layer of a predetermined layer thickness has been formed from the monolayers deposited in this way.

It is important here that at no time in the process is more than one precursor present in the process chamber. If both precursors are present at the same time, the two precursors already react with each other before being deposited. This causes CVD (chemical vapor deposition) processes, which lead to nucleus and particle formation and are detrimental to the conformity and homogeneity of the deposited layer.

The removal of the precursors conventionally takes place in the course of a process cycle by evacuation by means of a pumping device, which largely evacuates the process chamber. Such a method is known from U.S. Pat. No. 5,916,365 (Sherman).

According to a further customary method, the precursors are respectively forced out of the process chamber by means of a chemically inert purging gas.

The removal of the precursor (hereafter the purging step) takes up a significant proportion of the overall duration of a process cycle. The duration of a process cycle is made up of the time during which the precursor is deposited, typically 200 to 500 milliseconds, and the duration of the purging steps, typically approximately 3 seconds. Shorter purging times can be realized for removing a precursor by means of a vacuum pump than by means of a purging operation. A monomolecular monolayer formed within a process cycle of approximately 5 seconds has a layer thickness of approximately 1 Angström. The depositing of a layer of 20 nanometers then requires a process duration of approximately 20 minutes. The long duration of the process determines the process costs or restricts the throughput of substrates at a process reactor.

### SUMMARY

One embodiment of the present invention provides a method for depositing a layer by means of sequential gas phase deposition which permits shorter process cycle times and a higher throughput of substrates at a process reactor in comparison with conventional methods. One embodiment of the invention provides a process reactor for sequential gas phase deposition which permits shorter process cycle times for the depositing of a layer in comparison with conventional ALD reactors.

According to one embodiment of the invention, the removal of a process gas from a process chamber of a process reactor takes place by at least partial pressure equalization of a pressure difference between the process chamber and an auxiliary chamber in which a significantly lower auxiliary pressure prevails at the beginning of the pressure equalization. The pressure equalization has the effect that the process gas in the process chamber is rarefied by several orders of magnitude.

In one case, the auxiliary pressure is at most one tenth of the process pressure. The auxiliary chamber in one embodiment has a volume that corresponds at least to ten times a volume of the process chamber. For process chambers for ALD processes, generally small chamber volumes are desired, to accelerate the diffusion-determined depositing process. ALD process chambers typically have a cross-sectional area that is just adequate for receiving the substrate and a very small height of just a few centimeters. Even large-volume auxiliary chambers with approximately 50 times or 100 times the chamber volume of the process chamber can be readily realized in a practical way.

In one embodiment, the substrate to be processed is located in a process chamber with a small volume during the deposition. During the deposition of a precursor, a process pressure prevails in the process chamber. A much lower pressure than the process pressure, the auxiliary pressure, prevails in the auxiliary chamber.

After the deposition of the precursor, the process gas can then be removed very rapidly from the process chamber by an equalization of pressure or concentration being brought about between the process chamber and the auxiliary chamber.

In a method according to one embodiment of the invention, the pressure difference between the auxiliary pressure and the process pressure is maintained during the introduction of the process gases by means of a differential pumping device. The pressure equalization is then brought about at least partly by switching off the differential pumping device. In comparison with conventional methods of evacuating the process chamber by means of pumping, according to one embodiment of the invention the emptying of the process chamber is supported by the pressure gradient between the process chamber and the auxiliary chamber.

According to another method according to one embodiment of the invention, the process chamber and the auxiliary chamber are hermetically sealed from each other by means of a controllable separating device during the introduction of one of the process gases or during the deposition. For the pressure equalization, the separating device is opened. The separating device can be configured in such a way that the pressure equalization takes place over a large cross-sectional area. If opening and closing of the separating device is hydraulically supported, a very rapid rarefaction of the process gas is brought about by the opening of the separating device.

After the rarefying of the process gas in the process chamber, if a differential pumping device is used the differential pumping device is put into operation again. If a hermetic separating device is used, this is closed and the pressure in the auxiliary chamber is reduced again to the auxiliary pressure.

After putting the differential pumping device into operation or closing the separating device, a further process gas is fed to the process chamber. The further process gas forces residual fractions of the first process gas that are still in the process chamber out of the process chamber.

In one embodiment, however, flowing back of the first process gas into the process chamber is avoided by a controllable valve device and/or by introducing the further process gas already during the pressure equalization. The further process gas is in one case such a gas that contains a further precursor and is fed in under process conditions, which preclude direct reaction with the precursor contained in the first process gas.

According to another method according to one embodiment of the invention, a chemically inert purging gas is provided as the further process gas.

The time required for the purging step can be reduced further if, as provided according to one embodiment of the method according to one embodiment of the invention, the auxiliary chamber is evacuated continuously, that is both during the pressure equalization and during the deposition in the process chamber.

An evacuation or removal of residual fractions of the first process gas from the auxiliary chamber while at the same time introducing a further process gas into the process chamber to continue the deposition permits virtually parallel operation of the reaction chamber and the auxiliary chamber in a way which is not conventionally possible. The virtually parallel operation of the process chamber and the auxiliary chamber considerably reduces the time requirement for a process cycle of a depositing process, since the removal of the first process gas takes place partly at the same time as the depositing of the precursor from a further process gas.

The method according to one embodiment of the invention can be carried out with a process reactor according to one embodiment of the invention for producing a layer on a substrate arranged in a process chamber of the process reactor by means of a sequential gas phase deposition, in the course of which at least one first process gas and one second process gas are respectively introduced into the process chamber and removed from the process chamber alternately one after the other. In this case, the process reactor has according to one embodiment of the invention an auxiliary chamber for the rarefaction of at least one of the process gases, which auxiliary chamber can be evacuated to an auxiliary pressure significantly lower than a process pressure prevailing in the process chamber during the deposition and is to be alternately connected to the process chamber or separated from the process chamber.

Arranged between the auxiliary chamber and the process chamber is a controllable separating device, which in a closed state closes the process chamber with respect to the auxiliary chamber and in an opened state connects the process chamber to the auxiliary chamber.

Provided as an alternative or in addition to the separating device is a differential pumping device, which produces a pressure difference prevailing between a process pressure in the process chamber and an auxiliary pressure in the auxiliary chamber.

In addition, the process chamber has a valve device. The valve device prevents flowing back of a process gas from the auxiliary chamber into the process chamber.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic cross section through a process reactor according to one embodiment of the invention.

FIG. 2 illustrates a schematic cross section through a process reactor according to one embodiment of the invention.

FIG. 3 illustrates a schematic cross section through the process reactor according to one embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

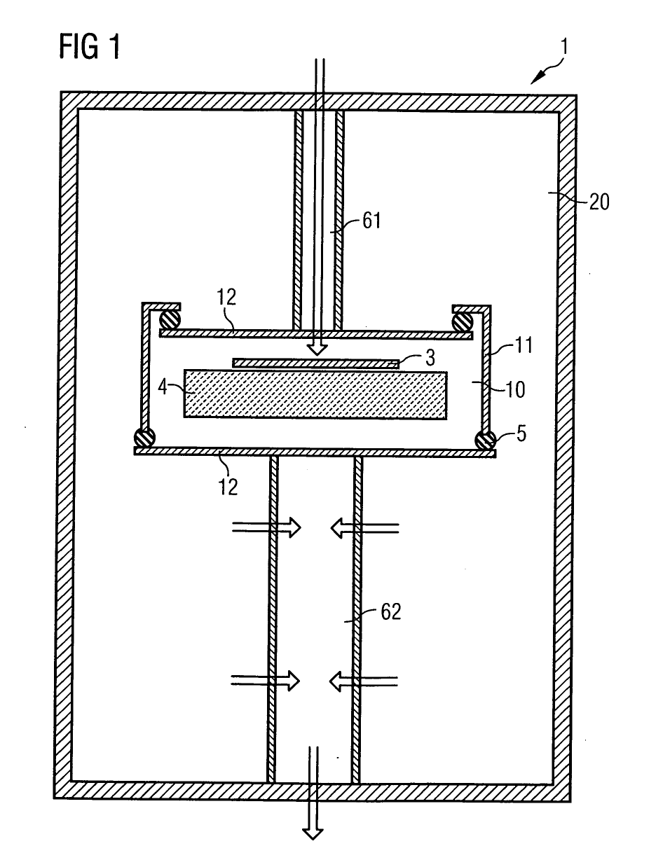

In FIG. 1, a process reactor 1 with a process chamber 10 and an auxiliary chamber 20 is represented, the auxiliary chamber 20 surrounding the process chamber 10 on all sides. The process chamber 10 has a chamber wall 12, which together with a separating device 11, hermetically seals the process chamber 10 with respect to the auxiliary chamber 20 in the closed state that is shown. Provided inside the process chamber 10 is a susceptor 4, on which a substrate 3 rests. Arranged between the chamber wall 12 and the separating device 11, which can be moved toward the chamber wall 12, are seals 5. In the closed state of the separating device 11, the seals 5 hermetically close off the process chamber 10 with respect to the auxiliary chamber 20 adjoining the process chamber 10.

During the deposition, a process gas is introduced into the process chamber 10 via feeds 61. At the same time, the auxiliary chamber 20 is evacuated via a suction discharge device 62. After depositing a first precursor comprising a first process gas, the separating device 11 is opened with hydraulic support, for instance by swinging up or by displacement in the vertical or horizontal direction. Since a significantly higher process pressure prevails in the process chamber 10 than in the auxiliary chamber 20, the process gas will leave the process chamber 10 and fill the auxiliary chamber 20. This process is supported by simultaneous introduction of a further process gas, for instance a purging gas, by means of the feeds 61. By continued evacuation of the auxiliary chamber 20 via discharges 62, a pressure difference is maintained between the process chamber 10 and the auxiliary chamber 20, supporting the expulsion of the first process gas from the process chamber 10. After a time which is short in comparison with conventional purging steps, the separating device 11 is closed again with hydraulic support. Parallel to this, the auxiliary chamber 20 is evacuated further and residual fractions of the process gases are removed. This operation continues while at the same time the deposition with the following precursor is controlled in the process chamber 10.

The time taken for the removal of a process gas from the process chamber 10 is significantly reduced in comparison with conventional methods in customary ALD process reactors.

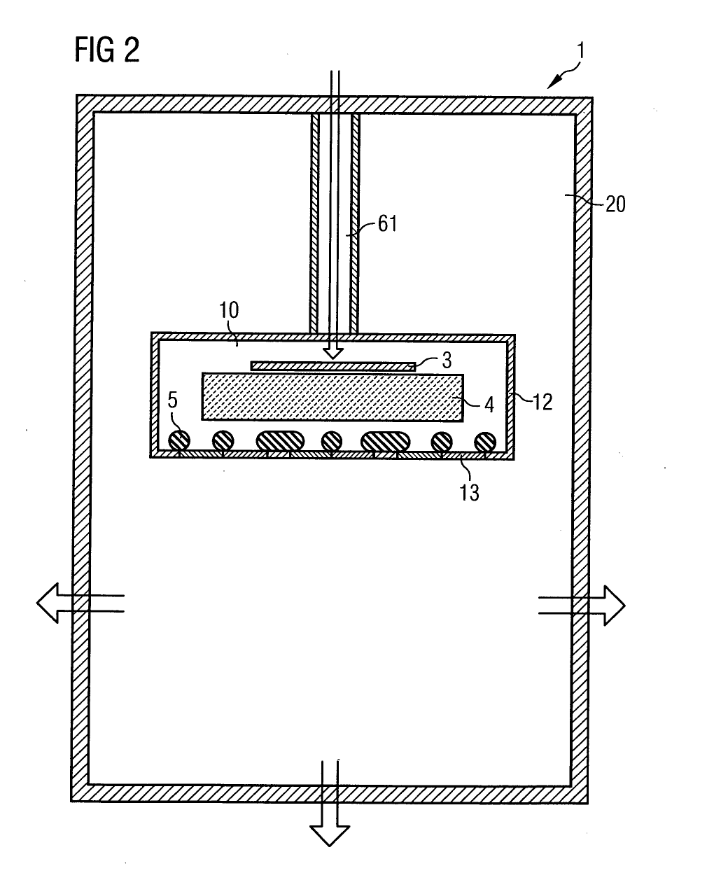

The process reactor according to one embodiment of the invention that is schematically represented in FIG. 2 differs from the process reactor that is represented in FIG. 1 by the configuration and arrangement of the separating device. In the exemplary embodiment of the process reactor according to the embodiment of the invention that is represented in FIG. 2, a plurality of flaps 13 are provided as the separating device. The flaps 13 and seals 5 assigned to the flaps 13 are arranged outside a heated region of the process chamber 10. The heated region of the process chamber 10 is in this case generally the region of the process chamber 10 oriented toward a substrate surface to be processed.

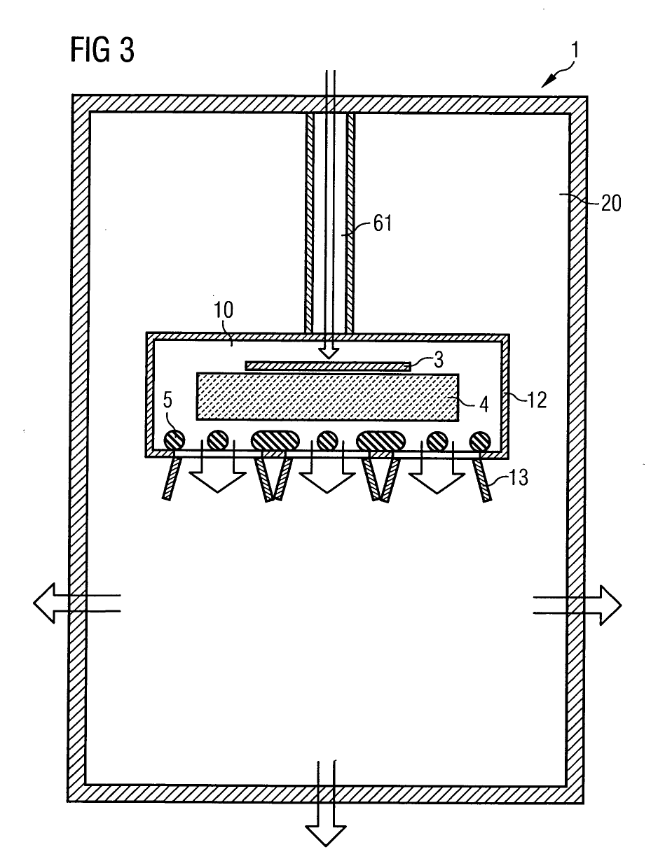

In FIG. 3, the flaps 13 of the exemplary embodiment from FIG. 2 are represented in the opened state. A multiplicity of downwardly opened flaps 13 achieves the effect of a large opening cross section between the process chamber 10 and the adjoining auxiliary chamber 20 in a very short time. The arrangement of the flaps 13 lying opposite the feeds 61 achieves the effect that, with simultaneous introduction of a purging gas via the feeds 61, an expulsion of the process gas from the process chamber 10 is supported.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1-15. (canceled)

16. A method for depositing a layer on a substrate arranged in a process chamber of a process reactor by means of a sequential gas phase deposition, the method comprising:
introducing at least one first process gas and one second process gas into the process chamber;
removing at least one first process gas and one second process gas from the process chamber alternately one after the other;
wherein, for the partial removal of at least one of the process gases, the process gas is rarefied by an at least partial pressure equalization of a pressure difference present between a process pressure prevailing in the process chamber and an auxiliary pressure in an auxiliary chamber of the process reactor that is significantly lower at the beginning of the pressure equalization.

17. The method of claim 16, further including providing the auxiliary pressure at the beginning of the pressure equalization with at most one tenth of the process pressure.

18. The method of claim 17, further including providing the auxiliary chamber with at least ten times a volume of the process chamber.

19. The method of claim 16, further including maintaining the pressure difference between the process pressure and the auxiliary pressure during the introduction of one of the process gases by a pumping operation acting between the auxiliary chamber and the process chamber and bringing the pressure equalization about at least partly by ending the pumping operation.

20. The method of claim 16, further including producing the pressure difference between the process pressure and the auxiliary pressure while one of the process gases is being introduced by means of a separating device hermetically sealing the process chamber with respect to the auxiliary chamber in a closed state and pumping out of the auxiliary chamber, and bringing the pressure equalization about at least partly by opening of the separating device.

21. The method of claim 16, further including building up the pressure difference between the process pressure and the auxiliary pressure after the rarefaction of a first process gas by a pumping operation of a pumping device producing a pressure difference prevailing between the process pressure in the process chamber and the auxiliary pressure in the auxiliary chamber and closing of the separating device and evacuation of the auxiliary chamber.

22. The method of claim 21, wherein, after the switching on of the pumping device and the closing of the separating device, a further process gas is introduced into the process chamber and residual fractions of the first process gas that are in the process chamber are forced out of the process chamber.

23. The method of claim 16, further including providing a valve device to avoid flowing back of the process gas into the process chamber.

24. The method of claim 16, further including introducing a further process gas into the process chamber to avoid flowing back of the process gas into the process chamber.

25. The method of claim 22, wherein a chemically inert purging gas is provided as the further process gas.

26. The method of claim 16, further including evacuating the auxiliary chamber during the pressure equalization.

27. The method of claim 16, further including introducing a second process gas, having a precursor intended for deposition, into the process chamber during the evacuation of the auxiliary chamber.

28. A process reactor comprising:
a process chamber configured for producing a layer on a substrate by means of a sequential gas phase deposition, wherein at least one first process gas and one second process gas are respectively introduced into the process chamber and removed from the process chamber alternately one after the other;
a susceptor configured inside the process chamber and on which the substrate rests;
feeds for introducing process gases; and
an auxiliary chamber for rarefaction of at least one of the process gases, wherein the auxiliary chamber can be evacuated to an auxiliary pressure significantly lower than a process pressure prevailing in the process chamber during the deposition and is to be alternately connected to the process chamber and separated from the process chamber.

29. The process reactor of claim 28, further comprising a separating device having a closed state that closes the process chamber with respect to the auxiliary chamber and having an opened state that connects the auxiliary chamber and the process chamber.

30. The process reactor of claim 28, further comprising a pumping device producing a pressure difference acting between the process pressure in the process chamber and the auxiliary pressure in the auxiliary chamber.

31. The process reactor of claim 28, further comprising a valve device blocking flowing back of a process gas from the auxiliary chamber into the process chamber.

32. A process reactor comprising:
a process chamber configured to produce a layer on a substrate using sequential gas phase deposition, wherein a first process gas and a second process gas are introduced into the process chamber and also removed from the process chamber;
a susceptor configured inside the process chamber and on which the substrate rests;
feeds for introducing process gases;
an auxiliary chamber for rarefaction of at least one of the process gases; and
means between the process chamber and auxiliary chamber for evacuating the auxiliary chamber to an auxiliary pressure significantly lower than a process pressure prevailing in the process chamber.

33. The process reactor of claim 32, wherein the means for evacuating further includes means for alternately connecting and separating the process chamber and the auxiliary chamber.

34. The process reactor of claim 32, further comprising a pumping device producing a pressure difference acting between the process pressure in the process chamber and the auxiliary pressure in the auxiliary chamber.

35. The process reactor of claim 32, further comprising a valve device blocking flowing back of the process gas from the auxiliary chamber into the process chamber.
